(19) United States
(12) Patent Application Publication
(10) Pub. No.: US 2015/0294738 A1
(43) Pub. Date: Oct. 15, 2015

(54) TEST STRUCTURE AND METHOD OF TESTING A MICROCHIP

(71) Applicant: INTERNATIONAL BUSINESS MACHINES CORPORATION, Armonk, NY (US)

(72) Inventors: Ishtiaq AHSAN, Wallkill, NY (US); Fred J. TOWLER, Essex Junction, VT (US); Robert C. WONG, Poughkeepsie, NY (US)

(73) Assignee: INTERNATIONAL BUSINESS MACHINES CORPORATION, Armonk, NY (US)

(21) Appl. No.: 14/253,235

(22) Filed: Apr. 15, 2014

(51) Int. Cl. G11C 29/48; G11C 29/56

(52) U.S. Cl. CPC G11C 29/48; G11C 29/56

(57) ABSTRACT

A tristate inverter array test structure and method of testing structures in a microchip are disclosed. The structure includes: a PFET stack in series with an NFET stack; an inverted wordline driving a PFET of the PFET stack; a worldline driving an NFET of the NFET stack; a data_in line connecting to an input of the PFET stack and the NFET stack; and a data_out line connecting to an output of the PFET stack and the NFET stack.

### FIELD OF THE INVENTION

The invention relates to semiconductor structures and, more particularly, to a tristate inverter array test structure and method of testing structures in a microchip.

### BACKGROUND

Early technology development needs a rapid way to find and isolate defects in new technology to speed up early learning of the fabrication processes. The SRAM (Static Random Access Memory) bitcell array has been traditionally used as a yield learning vehicle for such new technologies. However, the yield of the SRAM bitcell is susceptible to parametric variations and subtle process defects/variations, particularly in transistor characteristics. This makes it difficult to isolate defects other than associated with transistor characteristics, particularly in a large chip area.

In new technologies, as processing becomes more mature and less transistors actually fail, the defects become more subtler on an area basis. However, it becomes ever more difficult to determine other types of failures using an SRAM array in such mature processes, particularly in view of the fact that the SRAM will still have transistor failure due to its own sensitivity. As such, it becomes necessary to look at a larger chip area for fails, making the detection process that more time consuming and expensive.

### SUMMARY

In an aspect of the invention, a structure comprises: a PFET stack in series with an NFET stack; an inverted wordline driving a PFET of the PFET stack; a worldline driving an NFET of the NFET stack; a data_in line connecting to an input of the PFET stack and the NFET stack; and a data_out line connecting to an output of the PFET stack and the NFET stack.

In an aspect of the invention, a tristate inverter array comprises: a first PFET in series with a second PFET; an inverted wordline driving the second PFET; a first NFET in series with a second NFET, with the second NFET being in series with the second PFET; and a wordline driving the second NFET.

In an aspect of the invention, a method, comprises: inputting a known input signal into a tristate inverter array; detecting an output signal of the tristate inverter array; and determining whether the output signal matches the input signal and, if so, determining a defect in a structure on a microchip.

### BRIEF DESCRIPTION OF THE SEVERAL VIEWS OF THE DRAWINGS

The present invention is described in the detailed description which follows, in reference to the noted plurality of drawings by way of non-limiting examples of exemplary embodiments of the present invention.

FIG. 1 shows a conventional SRAM cell used to detect defects in early technologies;

FIG. 2 shows a tristate inverter array cell in accordance with aspects of the present invention;

FIG. 3 shows a failure analysis graph of types of defects and related percentages physically found with an SRAM cell and the tristate inverter array of the present invention; and

FIG. 4 shows a process flow in accordance with aspects of the present invention.

### DETAILED DESCRIPTION

The invention relates to semiconductor structures and, more particularly, to a tristate inverter array test structure and method of testing structures in a microchip. In embodiments, the tristate inverter array of the present invention is a robust design that is less susceptible to parametric variation or subtle systematic process defects and hence is very useful to extract yield signals caused by processing defects (e.g., metal interconnect issues, missing contacts, etc.). That is, the tristate inverter array is more immune to transistor characteristics than a conventional SRAM cell. As the yield of the tristate inverter array is much greater than the SRAM array, it is capable of highlighting different types of defects, e.g., other than attributable to transistor characteristics. Also, advantageously, the tristate inverter array retains all the useful features of the traditional SRAM array, e.g., mappability of fails, ease of isolation fails, regularity in design, etc., and can compliment traditional SRAM methodologies.

In embodiments, the tristate inverter array of the present invention is a test structure which allows the tester/designer/process engineer to see beyond the early device problems and learn hard defects, e.g., metal interconnect fails, etc., even when a transistor characteristic causes a SRAM cell to fail. In this way, the tristate inverter array can pin-point and quantify particular offending constructs, complimenting the SRAM cell. For example, the tristate inverter array of the present invention can be configured with a SRAM half-cell to determine the severity of defects due to the cell crosscoupling, amongst other things.

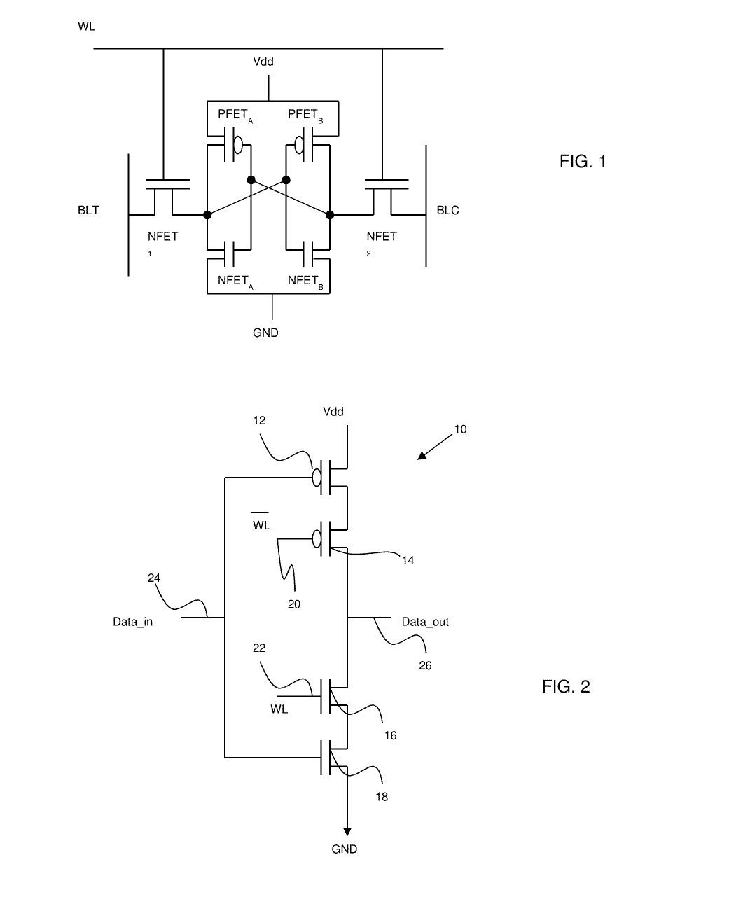

FIG. 1 shows a conventional SRAM cell used in an array of SRAM cells. The conventional SRAM cell includes NFET₁ and NFET₂ connected to a wordline (WL). The NFET₁ and NFET₂ are also connected to a bitline true (BLT) and bitline complimentary (BLC), respectively. The SRAM cell also includes two latching devices, e.g., NFET_{A} and NFET_{B}, with their sources in common with PFET_{A} and PFET_{B}, respectively. As should be understood by those of skill in the art, in an array of SRAM cells, the wordline (WL), bitline true (BLT) and bitline complimentary (BLC) will connect to the NFET₁ and NFET₂ of each cell, in the manner described herein.

As the bitlines BLT and BLC are used for both write and read, these operations cannot happen simultaneously. Specifically, in a write operation, the bitline BLT or BLC is pulled to GND and the opposite side is held to Vdd. The WL is then raised, which transitions the data state to the internal nodes of the cell, e.g., NFET_{A}, NFET_{B}, PFET_{A} and PFET_{B}. WL then goes to GND, isolating the cells from the bitlines BLT and BLC such that the data state is held inside the cell. In a read operation, on the other hand, the bitlines BLT and BLC are precharged to Vdd and when the WL is raised, the bitlines BLT and BLC will pull low depending on the data state in order to read out the data. Successful operation of the SRAM cell is very dependent upon the strength ratios between a pass gate, pull up and pull down devices.

A fail of the SRAM cell is indicative of a defect in a transistor characteristic in the new technology, perhaps associated with processing parameters. For example, the SRAM cell is determined to be in a “fail” state when the output data state does not match the known input data state, i.e., the cell did not successful retain the data. In the SRAM cell, the failing locations are easily mapped and the matrix nature of the cell layout makes finding the failing cell easy. However, due to the sensitivity of the SRAM cell, the failure is almost entirely attributed to a transistor characteristic, compared to, for example, a metal interconnect fail or other defect.

FIG. 2 shows a tristate inverter array cell in accordance with aspects of the present invention. In the configuration shown in FIG. 2, the tristate inverter array 10 is much less susceptible to both parametric variation and subtle process defects while retaining all the useful features of the SRAM array (e.g., fail mappability, ease of isolation of fails, regular design). More specifically, the tristate inverter array 10 includes a PFET stack, i.e., PFETs 12, 14, and a NFET stack, i.e., NFETs 16, 18, in series. The PFET 12 is connected to an inverted wordline 20; whereas, the NFET 16 is connected to worldline. In this way, the inverted wordline 20 will drive the PFET 14 and the wordline 22 will drive the NFET 18 as discussed herein. The tristate inverter array 10 further includes a data_in line 24 and data_out line 26. Advantageously, there is no minimal strength dependence, as long as the on resistance of the PFET stack, i.e., PFETs 12, 14, is less than the off resistance of the NFET stack, i.e., NFETs 16, 18 (or vice versa).

In operation, an inverted signal detected at the data_out line 26 is indicative of an acceptable structure, e.g., no processing defects such as metal interconnect issues, missing contacts, etc. As the tristate inverter array 10 is not sensitive to transistor defects (particularly later in the maturity curve when an SRAM remains sensitive), a non-inverted signal at the data_out line 26 can now be attributable to processing defects such as metal interconnect issues, missing contacts, etc.

By way of more specific example, when the data_in signal is asserted as GND, the PFET 12 turns on and passes Vdd to PFET 14 (which is connected to the inverted wordline 2). In this way, the data_out signal will be Vdd. This data_out signal is indicative of no hard process defects with the new technology. If, though, the data_out signal is not inverted from the data_in signal, e.g., GND, the extracted yield signal (data_out) is likely indicative of hard process defects in the new technology. On the other hand, when the data_in signal is Vdd, the NFET 18 will turn on and GND is passed through the wordline 22 to the NFET 16. In this way, the data_out signal will be GND. This data_out signal is indicative of no hard process defects with the new technology. If, though, the data_out signal is not inverted, e.g., Vdd, from the data_in signal, the extracted yield signal (data_out) is likely indicative of hard process defects in the new technology.

Also, it should be understood by those of ordinary skill in the art that by implementing the tristate inverter array 10, there is no requirement to store data. That is, in operation, as the read and write are provided in the same cycle, storing the data between a read and write cycle is not required. Accordingly, in the tristate inverter array 10, there is no memory requirement as the data path is fully exercised in a single cycle. Moreover, the tristate inverter array 10 allows rapid testing using memory testers; instead of analog measurements.

Table 1, below, shows increased values required for a failure detection of the tristate inverter array 10, compared to a conventional SRAM. These values show that the tristate inverter array 10 is much less susceptible (more immune) to parametric variation or subtle systematic process defects than the conventional SRAM and, as such, will be able to be used to detect hard processing defects, when the conventional SRAM fails massively due to global transistor parameters.

TABLE 1

| | Value required | |
|---|---|---|
| Simulated parametric | to fail | Value required to fail |
| variation/defect | traditional SRAM | tristate inverter array |
| Vt variation (Vt adder) | +P_Vfail | +P_Vfail: +320 mV |
| Vt variation (Vt subtractor) | −N_Vfail | −N_Vfail: +250 mV |
| NFET source-drain leakage | Cfail_N | Cfail_N: 4X |
| (conductance) | | |
| PFET source-drain leakage | Cfail_P | Cfail_P: 7X |
| (conductance) | | |
| NFET source-contact | Rfail | Rfail: 70X |
| resistance | | |
| SRAM Cross Couple Short | Diffusion Contact to | No Cross Couple |
| & Open | gate short, Contact | |
| | Open | |

More specifically, as shown in Table 1, the tristate inverter array 10 is more immune to increases in threshold (+P_Vfail) by +320 mV, as well as decreases in threshold (−N_Vfail) by +250 mV, than a conventional SRAM cell. In addition, the tristate inverter array 10 is 4× more immune to NFET leakage (when device is shut off) and 7× to PFET leakage than a conventional SRAM cell. The tristate inverter array 10 is also 70× more immune to resistance failures than a conventional SRAM cell.

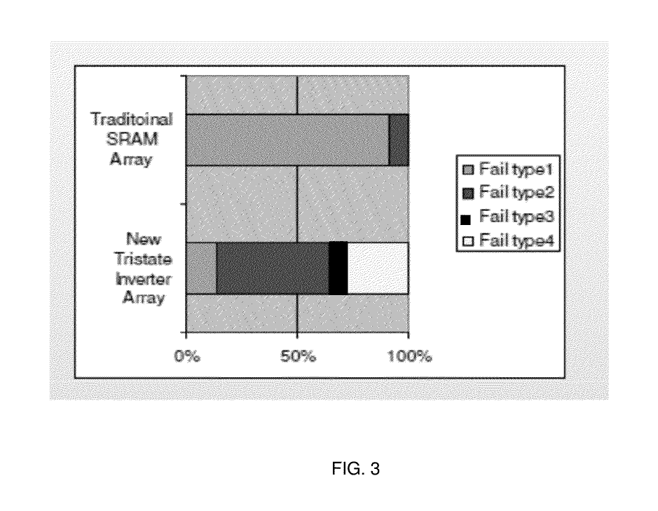

FIG. 3 shows a failure analysis graph of types of defects and related percentages physically found with an SRAM cell and the tristate inverter array of the present invention. In FIG. 3, the type 1 fail is representative of a transistor characteristic defect; whereas, the type 2, 3, and 4 fails are representative of a hard defect such as a metal interconnect defect, missing connections, devices that did not print, etc.

As shown in the graph of FIG. 3, the tristate inverter array 10 is capable of finding four types of defects, with the type 1, e.g., transistor characteristics, being only a small fraction of the total defects found. The type 1 fail defects found in the tristate inverter array 10 are defects that are nested within the SRAM cell, i.e., very bad defects in the transistor characteristics which may be difficult to locate using only the SRAM cell due to the overwhelming number of fails. The type 1 defects may be associated with, for example, implant transfer threshold blockages. In comparison, the SRAM predominately finds type 1 fails (greater than 95%) and only a small fraction of type 2 fails. The SRAM, due to its sensitivity, will not allow finding type 3 and 4 fails as the number of other fails mask them out.

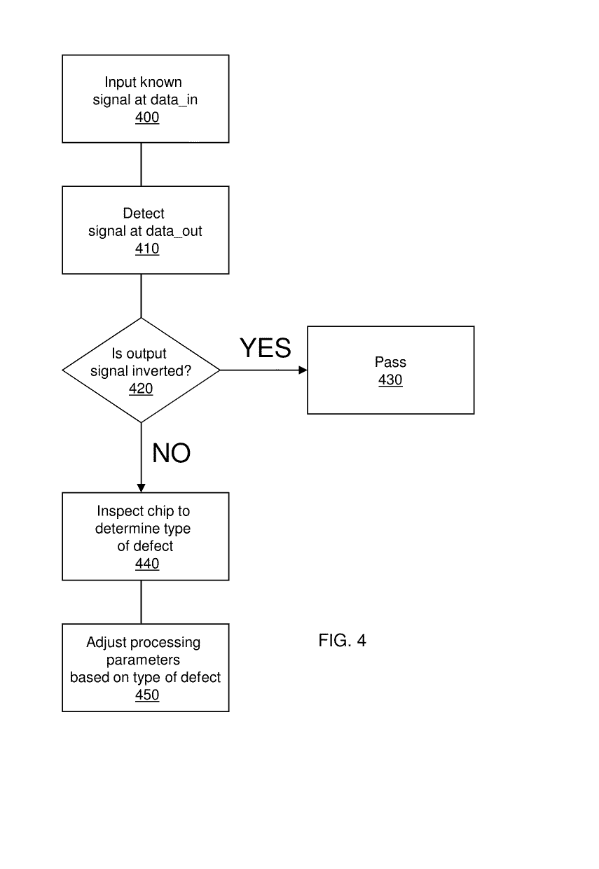

FIG. 4 shows a process flow in accordance with aspects of the present invention. At step 400, a known input signal is asserted into the tristate inverter array cell 10, e.g., assert a “1” or “0” at the data_in line. At step 410, an output signal (data_out) is detected at the data_out signal line of the tristate inverter array 10. The output signal (data_out) can be detected by a memory tester, for example. At step 420, a determination is made as to whether the output signal (data_out) is inverted from the input signal (data_in). If so, then the cell passes inspection at step 430. If the output signal (data_out) is not an inverted signal, then at step 440, a visual inspection is made to determine the type of defect. Based on the type of defect, the processing parameters can be adjusted at step 450. The steps 400-450 can be repeated until no defects are found in structures of a microchip, which were fabricated using the adjusted processing parameters.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A structure, comprising:
a PFET stack in series with an NFET stack;
an inverted wordline driving a PFET of the PFET stack;
a worldline driving an NFET of the NFET stack;
a data_in line connecting to an input of the PFET stack and the NFET stack; and
a data_out line connecting to an output of the PFET stack and the NFET stack.

2. The structure of claim 1, wherein:
the PFET stack comprises a first PFET and a second PFET in series; and
the NFET stack comprises a first NFET and a second NFET in series.

3. The structure of claim 2, wherein an on resistance of the PFET stack is less than an off resistance of the NFET stack.

4. The structure of claim 2, wherein an on resistance of the NFET stack is less than an off resistance of the PFET stack.

5. The structure of claim 2, wherein an inverted signal detected at the data_out line is indicative of a non-defective structure.

6. The structure of claim 2, wherein:
when a data_in signal is asserted as GND, the first PFET turns on and passes Vdd to the second PFET connected to the inverted wordline, and a data_out signal at the data_out line will be Vdd; and
the data_out signal of Vdd is indicative of no hard process defects.

7. The structure of claim 2, wherein:
when data_in signal is asserted as Vdd, the first NFET will turn on and GND is passed through the wordline to the second NFET and a data_out signal at the data_out line will be GND; and
the data_out signal of GND is indicative of no hard process defects.

8. The structure of claim 2, wherein read and write operations are performed in a single cycle.

9. The structure of claim 2, wherein the PFET stack and the NFET stack are less susceptible to parametric variation or systematic process defects than an SRAM cell.

10. The structure of claim 2, wherein:
a data_out signal detected at the data_out line is indicative of hard process defects;
the data_out signal is not inverted from a data_in signal asserted at the data_in line; and
the hard processing defects include at least one of a metal interconnect defect, a missing connection and devices that did not print.

11. A tristate inverter array, comprising:
a first PFET in series with a second PFET;
an inverted wordline driving the second PFET;
a first NFET in series with a second NFET, with the second NFET being in series with the second PFET; and
a wordline driving the second NFET.

12. The tristate inverter array of claim 11, further comprising a data_in signal line and a data_out signal line, wherein:
the data_in signal line connects to the first NFET and the first PFET; and
the data_out signal line connects to the second NFET and the second PFET.

13. The tristate inverter array of claim 12, wherein:
when a data_in signal at the data_in signal line is asserted as GND, the first PFET turns on and passes Vdd to the second PFET connected to the inverted wordline, and a data_out signal will be Vdd at the data_out signal line; and
the data_out signal of Vdd is indicative of no hard process defects.

14. The tristate inverter array of claim 12, wherein:
when data_in signal at the data_in signal line is asserted as Vdd, the first NFET will turn on and GND is passed through the wordline to the second NFET and a data_out signal will be GND at the data_out signal line; and
the data_out signal of GND is indicative of no hard process defects.

15. The tristate inverter array of claim 12, wherein a data_out signal is indicative of hard process defects with new technology.

16. The tristate inverter array of claim 15, wherein the data_out signal is inverted from a data_in signal.

17. The tristate inverter array of claim 16, wherein the hard processing defects include at least one of a metal interconnect defect, a missing connection and devices that did not print.

18. The tristate inverter array of claim 12, wherein a read and write operation are provided in a same cycle.

19. A method, comprising:
inputting a known input signal into a tristate inverter array;
detecting an output signal of the tristate inverter array; and
determining whether the output signal matches the input signal and, if so, determining a defect in a structure on a microchip.

20. The method of claim 19, wherein the output signal is a non-inverted signal of the input signal, which is determinative of a defect.
